(19) United States
(12) Patent Application Publication
(10) Pub. No.: US 2026/0122874 A1
(43) Pub. Date: Apr. 30, 2026

(54) THREE-DIMENSIONAL MEMORY INCLUDING MULTI-LAYER CAPACITOR HORIZONTAL ELECTRODES AND MANUFACTURING METHOD THEREFOR

(71) Applicant: IUCF-HYU (Industry-University Cooperation Foundation Hanyang University), Seoul (KR)

(72) Inventors: Young Wook PARK, Seoul (KR); Sung Jun KIM, Seoul (KR); Jinho AHN, Seoul (KR); In-Sung PARK, Seoul (KR); Wangchul SHIN, Seoul (KR)

(73) Assignee: IUCF-HYU (Industry-University Cooperation Foundation Hanyang University), Seoul (KR)

(21) Appl. No.: 19/431,793

(22) Filed: Dec. 23, 2025

Related U.S. Application Data
(63) Continuation of application No. PCT/KR2024/005295, filed on Apr. 19, 2024.

(30) Foreign Application Priority Data
Jun. 23, 2023 (KR) 10-2023-0081285

(51) Int. Cl. H10B 12/00

(52) U.S. Cl. CPC H10B 12/03; H10B 12/30

(57) ABSTRACT

A three-dimensional memory including multi-layer capacitor horizontal electrodes and a manufacturing method therefor are disclosed. More specifically, a manufacturing method of a capacitor in a three-dimensional memory according to an example embodiment is configured to form each of the capacitor horizontal electrodes to have an increased horizontal area compared to each of the horizontal inter layer dielectrics.

### CROSS-REFERENCE TO RELATED APPLICATION(S)

This U.S. non-provisional application is a continuation application of PCT International Application PCT/KR2024/005295, which has an international filing date of Apr. 19, 2024, and claims priorities under 35 U.S.C. 119 to Korean Patent Application No. 10-2023-0081285, filed on Jun. 23, 2023, in the Korean intellectual property office, the disclosures of which are herein incorporated by reference in its entirety.

### BACKGROUND OF THE INVENTION

### Field of Invention

Example embodiments relate to a three-dimensional memory including multi-layer capacitor horizontal electrodes and a manufacturing method therefor.

### Description of Related Art

A semiconductor device such as a DRAM (Dynamic Random Access Memory) includes a MOS transistor having a source and a drain, a capacitor electrically connected to the source of the MOS transistor, and a wiring such as a bit line electrically connected to the drain of the MOS transistor.

In such a DRAM, a three-dimensional structure has been proposed in accordance with the trend toward higher integration, departing from a two-dimensional structure.

The three-dimensional DRAM separates a transistor and a capacitor and individually configures them, and by arranging multilayer capacitor horizontal electrodes spaced apart in a vertical direction when configuring the capacitor, it serves as an alternative capable of overcoming the limitations of refinement and high integration inherent in a two-dimensional DRAM.

However, in the conventional three-dimensional DRAM, the capacitor horizontal electrodes are limited to having a horizontal area identical to that of each of Horizontal inter layer dielectrics included in the capacitor, thereby presenting a limitation in capacitance values, which is proportional to the surface area of the capacitor horizontal electrodes.

Accordingly, there is a need for a technology capable of increasing the horizontal area of the capacitor horizontal electrodes to improve the capacitance values.

### BRIEF SUMMARY OF THE INVENTION

Example embodiments propose a three-dimensional memory including capacitor horizontal electrodes having an increased horizontal area compared to each of horizontal inter layer dielectrics and a manufacturing method therefor, in order to improve capacitance values.

More specifically, example embodiments propose a three-dimensional memory having a structure in which as each of selective deposition layers deposited on sacrificial layers protrudes in one direction of a horizontal direction beyond each of the horizontal inter layer dielectrics, each of the capacitor horizontal electrodes formed in spaces from which the selective deposition layers and the sacrificial layers have been removed protrudes in one direction of the horizontal direction beyond each of the horizontal inter layer dielectrics, and a manufacturing method therefor.

However, the technical problems intended to be solved by the present invention are not limited to the aforementioned problems, and various modifications may be made without departing from the spirit and scope of the present invention.

According to one embodiment, a manufacturing method of a capacitor in a three-dimensional memory may include preparing a semiconductor structure including horizontal inter layer dielectrics and sacrificial layers alternately stacked in a vertical direction; etching a separate trench in the semiconductor structure in the vertical direction; removing a portion of each side surface of the sacrificial layers through the separate trench; depositing each of selective deposition layers on each side surface of the sacrificial layers, from which the portion has been removed, through the separate trench; removing the selective deposition layers and the sacrificial layers; and forming each of capacitor horizontal electrodes in spaces from which the selective deposition layers and the sacrificial layers have been removed, and the depositing each of selective deposition layers may be configured to deposit each of selective deposition layers such that each of the selective deposition layers deposited on the sacrificial layers protrudes in one direction of a horizontal direction beyond each of the horizontal inter layer dielectrics.

According to an aspect, the forming each of capacitor horizontal electrodes may be configured to form each of the capacitor horizontal electrodes in spaces from which the selective deposition layers and the sacrificial layers, protruding in one direction of the horizontal direction beyond each of the horizontal inter layer dielectrics, have been removed.

According to another aspect, the capacitor horizontal electrodes may be configured to have a shape protruding in one direction of the horizontal direction beyond each of the horizontal inter layer dielectrics, as the capacitor horizontal electrodes are formed in spaces from which the selective deposition layers and the sacrificial layers, protruding in one direction of the horizontal direction beyond each of the horizontal inter layer dielectrics, have been removed.

According to another aspect, the forming each of the capacitor horizontal electrodes may be configured to form each of the capacitor horizontal electrodes to have an increased horizontal area compared to each of the horizontal inter layer dielectrics.

According to another aspect, the removing the selective deposition layers and the sacrificial layers may be configured to collectively remove the sacrificial layers and the selective deposition layers through a single process.

According to another aspect, the removing the selective deposition layers and the sacrificial layers may include etching a capacitor horizontal electrode trench in the semiconductor structure in the vertical direction; and removing the selective deposition layers and the sacrificial layers through the capacitor horizontal electrode trench.

According to another aspect, the etching a capacitor horizontal electrode trench in the vertical direction may further include depositing an insulating film to surround the semiconductor structure; and etching the capacitor horizontal electrode trench in the vertical direction on the insulating film.

According to another aspect, the manufacturing method of a capacitor in a three-dimensional memory may further include forming at least one capacitor dielectric so as to be in contact with at least one surface of each of the capacitor horizontal electrodes.

According to another aspect, the forming at least one capacitor dielectric may further include etching at least a portion of the semiconductor structure so that at least one surface of each of the capacitor horizontal electrodes is exposed.

According to another aspect, the manufacturing method of a capacitor in a three-dimensional memory may further include forming a capacitor vertical electrode so as to be in contact with at least one surface of the at least one capacitor dielectric.

According to another aspect, the removing a portion of each side surface of the sacrificial layers may be configured to selectively etch a portion of each side surface of the sacrificial layers using one of a dry etching method using a gas containing at least one of HCl and Cl2 and a wet etching method using a liquid containing at least one of KOH, TMAH, or ammonia water.

According to one embodiment, in a three-dimensional memory individually configuring a transistor and a capacitor, the capacitor may include horizontal inter layer dielectrics and capacitor horizontal electrodes alternately stacked in a vertical direction; and at least one capacitor dielectric formed so as to be in contact with at least one surface of each of the capacitor horizontal electrodes, and each of the capacitor horizontal electrodes may have a shape protruding in one direction of a horizontal direction beyond each of the horizontal inter layer dielectrics.

According to an aspect, each of the capacitor horizontal electrodes may be configured to have an increased horizontal area compared to each of the horizontal inter layer dielectrics.

According to another aspect, the capacitor may further include a capacitor vertical electrode formed so as to be in contact with at least one surface of the at least one capacitor dielectric.

Example embodiments may achieve technical effects of improving the capacitance values in a three-dimensional memory by proposing a three-dimensional memory including capacitor horizontal electrodes having an increased horizontal area compared to each of horizontal inter layer dielectrics and a manufacturing method therefor.

More specifically, example embodiments may propose a three-dimensional memory having a structure in which as each of selective deposition layers deposited on sacrificial layers protrudes in one direction of a horizontal direction beyond each of the horizontal inter layer dielectrics, each of the capacitor horizontal electrodes formed in spaces from which the selective deposition layers and the sacrificial layers have been removed protrudes in one direction of the horizontal direction beyond each of the horizontal inter layer dielectrics, and a manufacturing method therefor.

However, the effects of the present invention are not limited to those described above, and various other advantages may be realized without departing from the spirit and scope of the present invention.

### BRIEF DESCRIPTION OF THE DRAWINGS

These and/or other aspects, features, and advantages of the disclosure will become apparent and more readily appreciated from the following description of embodiments, taken in conjunction with the accompanying drawings of which:

FIG. 1A is a plan view illustrating a capacitor portion of a three-dimensional memory to explain a capacitor structure of the three-dimensional memory according to an example embodiment;

FIG. 1B is a side cross-sectional view illustrating the capacitor portion of the three-dimensional memory to explain the capacitor structure of the three-dimensional memory according to an example embodiment, corresponding to a cross-section taken along line A-A′ of FIG. 1A;

FIG. 2 is a flowchart illustrating a manufacturing method of a capacitor in a three-dimensional memory according to an example embodiment;

FIGS. 3A to 3K are plan views illustrating the capacitor portion of the three-dimensional memory to explain the manufacturing method of the capacitor in the three-dimensional memory shown in FIG. 2;

FIGS. 4A to 4K are side cross-sectional views illustrating the capacitor portion of the three-dimensional memory to explain the manufacturing method of the capacitor in the three-dimensional memory shown in FIG. 2, corresponding to cross-sections taken along line A-A′ of FIGS. 3A to 3J; and

FIGS. 5A and 5B are side cross-sectional views illustrating a conventional three-dimensional DRAM and a three-dimensional memory according to an example embodiment to explain superiority of a capacitor structure of the three-dimensional memory according to an example embodiment.

### DETAILED DESCRIPTION OF THE INVENTION

Hereinafter, embodiments of the present invention will be described in detail with reference to the accompanying drawings. However, the present invention is not limited by the embodiments. In addition, same reference numerals on the drawings may refer to same components throughout.

In addition, terminologies used herein are defined to appropriately describe the embodiments of the present invention and thus may be changed depending on a user, the intent of an operator, or a custom in the field to which the present invention pertains. Accordingly, the terminologies must be defined based on the following overall description of this specification. For example, in this specification, singular forms also include plural forms unless specifically stated otherwise in a phrase. In addition, the terms “comprising” and/or “comprises” used in the specification mean that the mentioned elements, steps, operations, and/or devices do not exclude existence or addition of one or more other elements, steps, operations, and/or devices. Also, although terms such as first, second, and the like are used in the specification to describe various areas, directions, shapes, and the like, these areas, directions, and shapes should not be limited by these terms. These terms are only used to distinguish one area, direction, or shape from another area, direction, or shape. Therefore, a part referred to as first part in one example embodiment may be referred to as second part in another example embodiment.

Moreover, it should be understood that various example embodiments of the present invention are not necessarily mutually exclusive although being different from each other. For example, specific shapes, structures, and characteristics described herein may be implemented in other embodiments without departing from technical idea and scope of the present invention in relation to one example embodiment. Besides, it should be understood that the location, arrangement, or configuration of individual components in each of presented categories of an example embodiment may be changed without departing from the technical idea and scope of the present invention.

Hereinafter, with reference to the drawings, a three-dimensional memory and a manufacturing method therefor according to example embodiments will be described in detail.

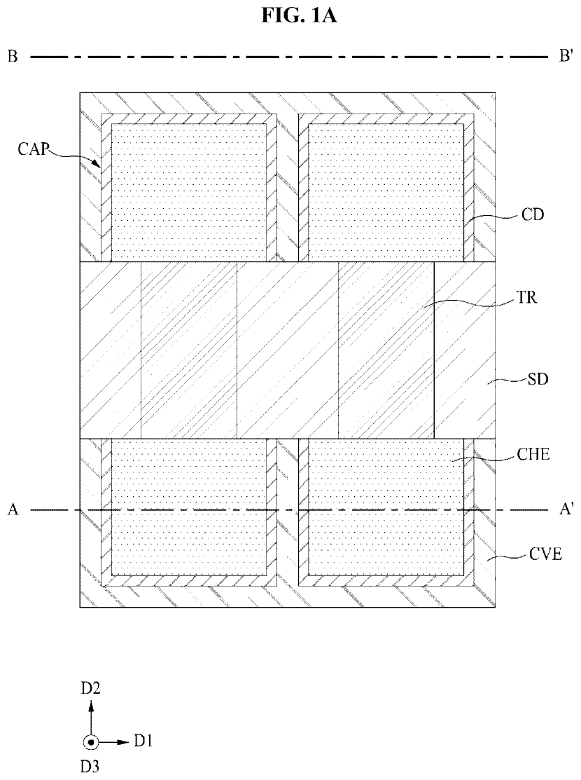

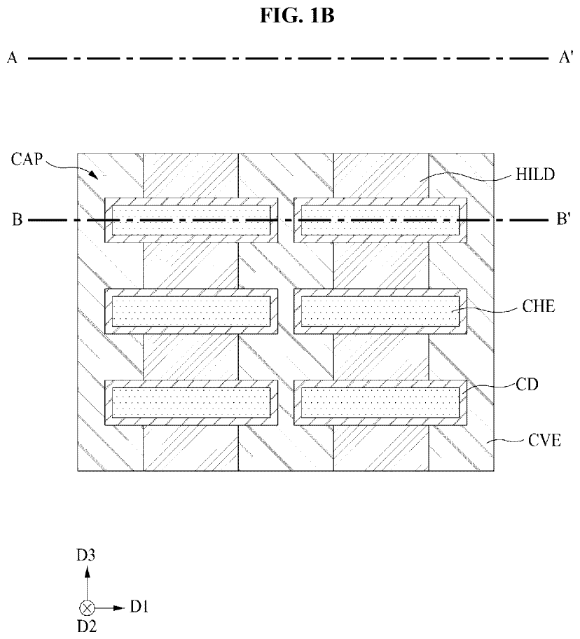

FIG. 1A is a plan view illustrating a capacitor portion of a three-dimensional memory to explain a capacitor structure of the three-dimensional memory according to an example embodiment, and FIG. 1B is a side cross-sectional view illustrating the capacitor portion of the three-dimensional memory to explain the capacitor structure of the three-dimensional memory according to an example embodiment, corresponding to a cross-section taken along line A-A′ of FIG. 1A.

Referring to FIGS. 1A and 1B, a three-dimensional memory according to an example embodiment is a memory individually configuring a TR (transistor) and a CAP (capacitor), and may be referred to as a multilayer capacitor memory by implementing, in the CAP, CHEs (capacitor horizontal electrodes) arranged in multiple layers in a vertical direction.

The TR of the three-dimensional memory may be configured to include a gate film (not shown) extending in a vertical direction (e.g., a third direction D3), a channel (not shown) in contact with at least one surface of the gate film in each of memory cell layers, and a source and a drain (not shown) in contact with at least one surface of the gate film in each of the memory cell layers, based on HILDs (horizontal inter layer dielectrics) and memory cell layers (not shown) alternately stacked in a vertical direction (e.g., the third direction D3) on a SUB (substrate).

The SUB may be a single-crystalline silicon substrate, and may include a conductive region, e.g., a well or an active region doped with impurities (for example, a p-type impurity). Also, in the SUB, a gate connection channel (not shown) connected to the gate film may be formed through high-concentration doping, and a SD (separate dielectric) surrounding an outer surface of the TR may be formed to separate individual devices.

The SD may be made of a dielectric material such as a low dielectric constant oxide film of SiO₂, Si₃N₄, SiON, and the like. The HILDs may also be formed of a dielectric material such as a low dielectric constant oxide film of SiO₂, Si₃N₄, SiON, and the like, thereby separating the memory cell layers from each other.

The gate film may be formed of a semiconductor material (e.g., polysilicon) or a conductive material (e.g., tungsten (W), copper (Cu), aluminum (Al), titanium (Ti), tantalum (Ta), molybdenum (Mo), ruthenium (Ru), gold (Au), platinum (Pt), iridium (Ir), titanium nitride (TiN), tantalum nitride (TaN), and the like), and may extend along the vertical direction (e.g., the third direction D3).

Since the channel, the source, and the drain may be arranged in each of the memory cell layers formed of a semiconductor material, the channel, the source, and the drain may be made of the same semiconductor material as that forming the memory cell layers. Additionally, the channel, the source, and the drain may be formed by doping impurities (e.g., p-type impurities) into the semiconductor material forming the memory cell layers.

In addition, the channel, the source, and the drain may be formed of different semiconductor materials. For example, the source and the drain may be formed of a first semiconductor material, and the channel may be formed of a second semiconductor material.

The thickness of each of the memory cell layers and the HILDs may range from about 10 nm to 100 nm, but is not limited thereto and may be adaptively adjusted according to the desired cell thickness and spacing between cells.

The TR, including the gate film, the channel, and the source and drain, may be electrically connected to a bit line (not shown) through the drain, and may be electrically connected to each of the CHEs included in the CAP through the source.

The described structure of the TR is merely exemplary, and the TR may be implemented in various structures required for the three-dimensional DRAM.

The CAP of the three-dimensional memory may be configured to include at least one CD (capacitor dielectric) formed in contact with at least one surface of each of the CHEs and CVEs (capacitor vertical electrodes) formed in contact with at least one surface of the at least one CD, based on the HILDs and the CHEs alternately stacked in the vertical direction (e.g., the third direction D3) on the SUB.

Because the outer surface of the CAP is surrounded by the SD described above, the CAP may be isolated for each device. Such SD may be formed of a dielectric material such as a low dielectric constant oxide film of SiO₂, Si₃N₄, SiON, and the like, as described previously.

Since the SUB may be shared with the TR, a detailed description thereof will be omitted.

As described above, the HILDs may also be formed of a dielectric material such as a low dielectric constant oxide film of SiO₂, Si₃N₄, SiON, and the like, thereby separating the CHEs by layer.

Each of CHEs may be formed of a semiconductor material (e.g., polysilicon) or a conductive material (e.g., tungsten (W), copper (Cu), aluminum (Al), titanium (Ti), tantalum (Ta), molybdenum (Mo), ruthenium (Ru), gold (Au), platinum (Pt), iridium (Ir), titanium nitride (TiN), tantalum nitride (TaN), and the like), and may be electrically connected to the source among the source and the drain included in the TR in each of the memory cell layers. As the formation method, ALD or CVD method may be used.

At this time, each of the CHEs may influence a capacitance value C of the CAP, as expressed by the following Equation 1.

C=ε(A/d) <Equation 1>

In Equation 1, ε denotes permittivity of at least one CD, A denotes the surface area of each of the CHEs, and d denotes the thickness of at least one CD.

Therefore, in order to improve the capacitance value C, each of the CHEs may have a shape protruding in one direction (e.g., a first direction D1) of the horizontal direction beyond each of the HILDs to have an increased horizontal area compared to each of the HILDs.

Such a structure, in which each of the CHEs protrudes in one direction (e.g., the first direction D1) of the horizontal direction beyond each of the HILDs, may be realized as a portion corresponding to spaces where the CHEs are to be formed (SLs (sacrificial layers)) and SDLs (selective deposition layers) deposited on each of the SLs protrude in one direction (e.g., the first direction D1) of the horizontal direction beyond each of the HILDs. This will be described in detail below with reference to a capacitor manufacturing method.

At least one CD may be formed of an insulating material (e.g., silicon nitride, aluminum oxide, hafnium oxide, zirconium oxide, titanium oxide, and the like) having dielectric properties such as a dielectric or a mixture thereof, while in contact with at least one surface of the CHEs.

The CVE, while in contact with at least one surface of at least one CD, may be formed of a semiconductor material (e.g., polysilicon) or a conductive material (e.g., tungsten (W), copper (Cu), aluminum (Al), titanium (Ti), tantalum (Ta), molybdenum (Mo), ruthenium (Ru), gold (Au), platinum (Pt), iridium (Ir), titanium nitride (TiN), tantalum nitride (TaN), and the like), and may extend along the vertical direction (e.g., the third direction D3).

Hereinafter, a manufacturing method of a capacitor in the described three-dimensional memory will be disclosed.

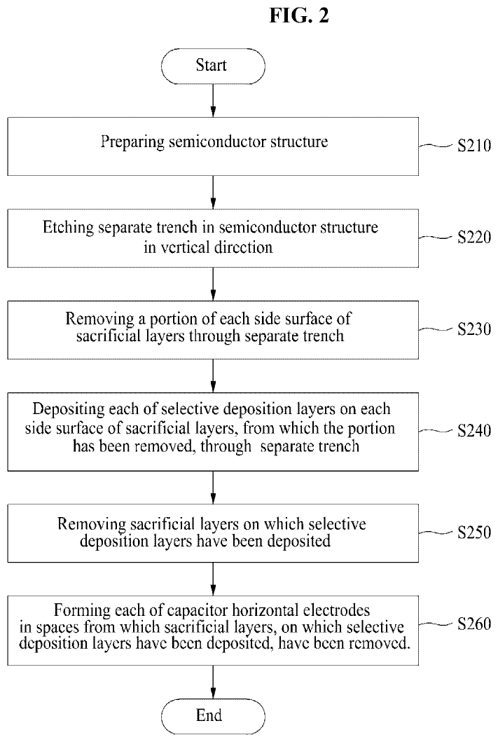

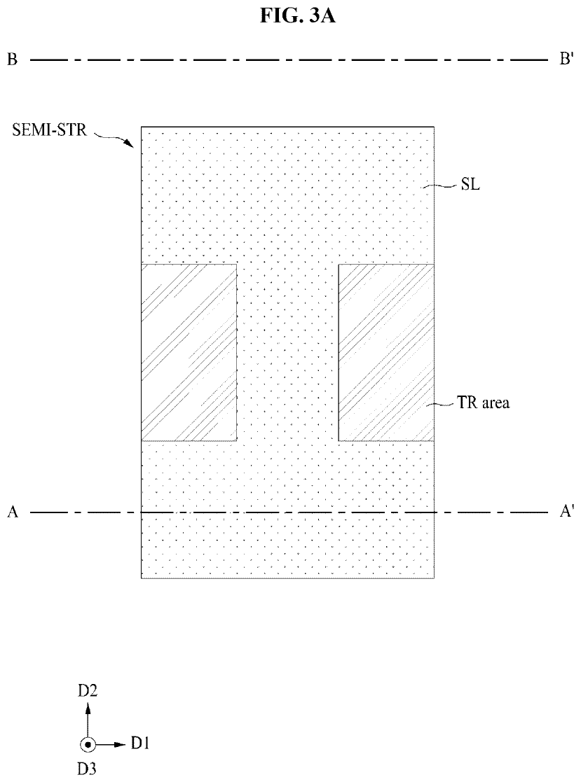

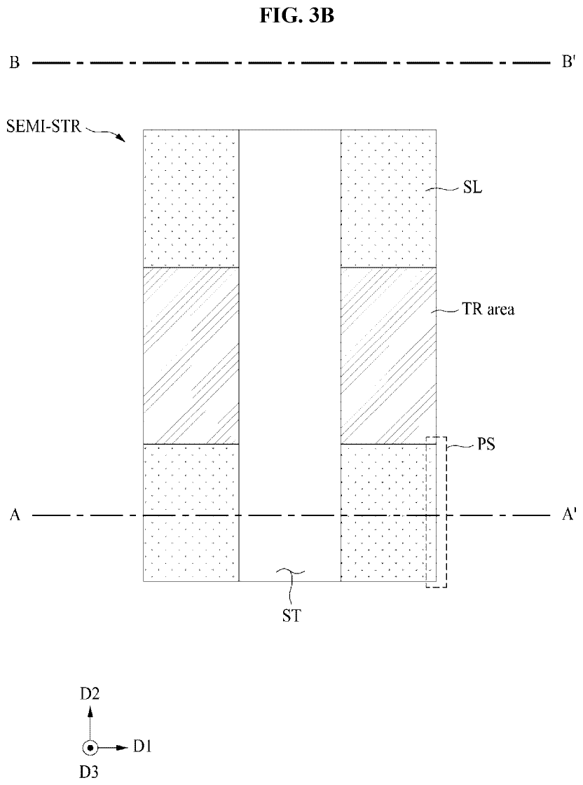

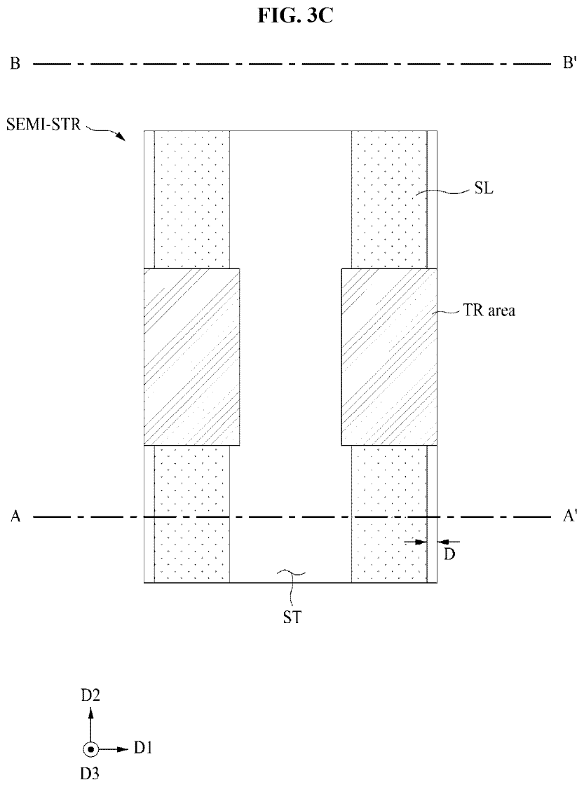

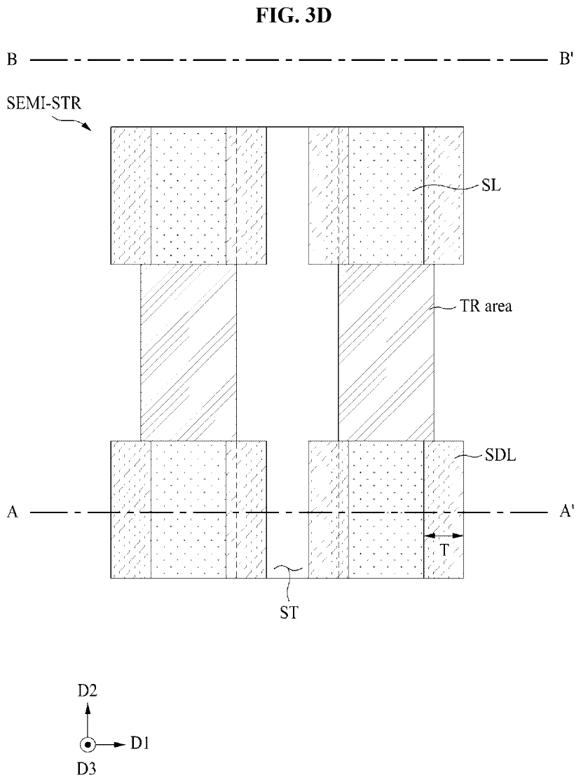

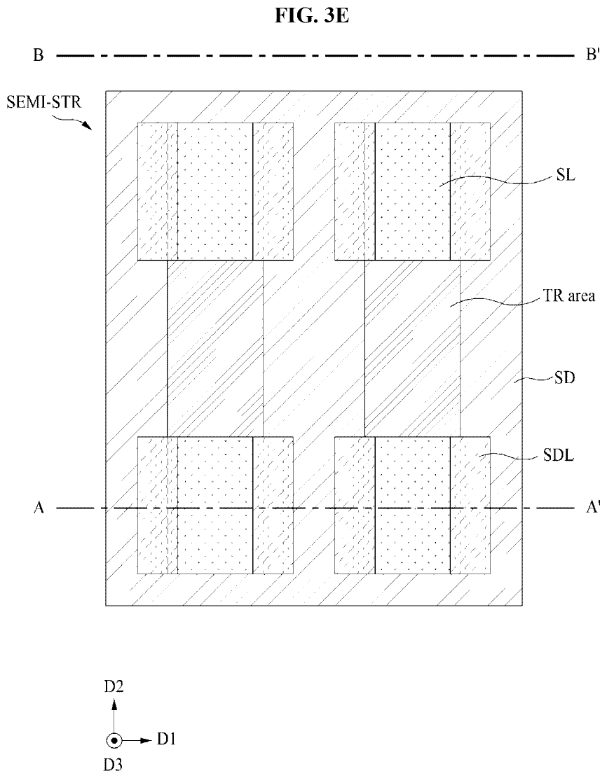

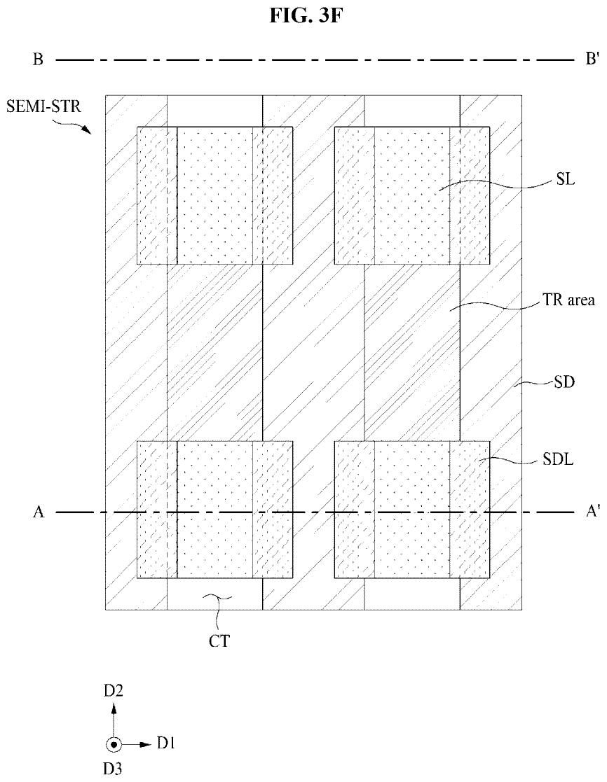

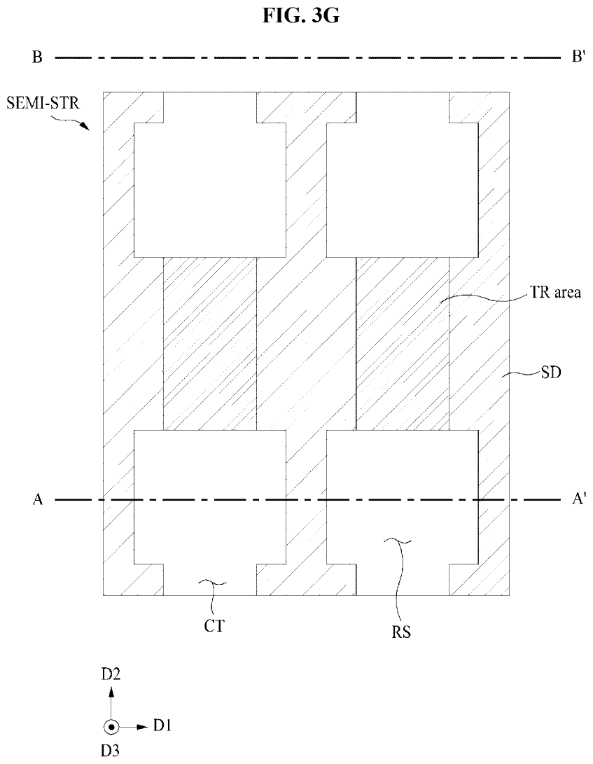

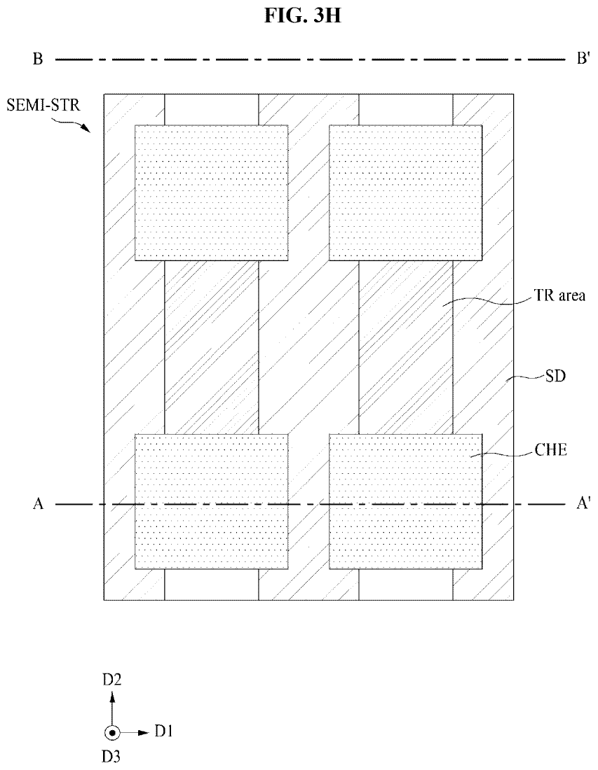

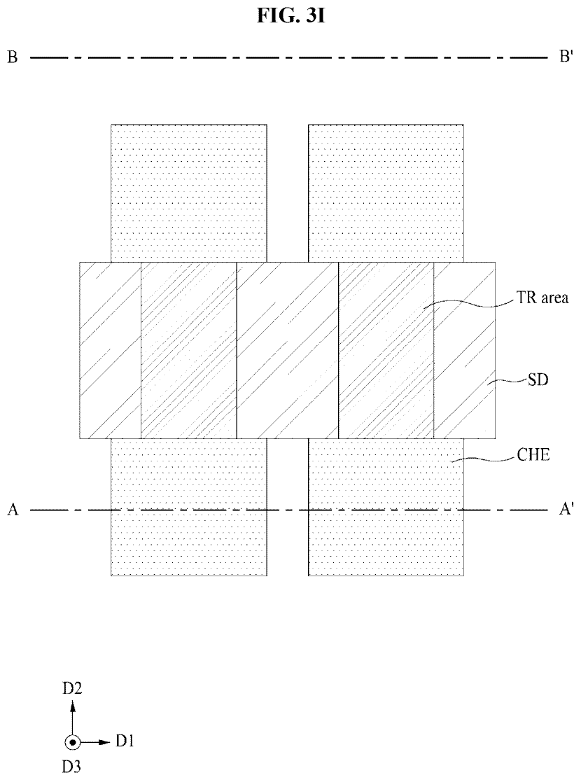

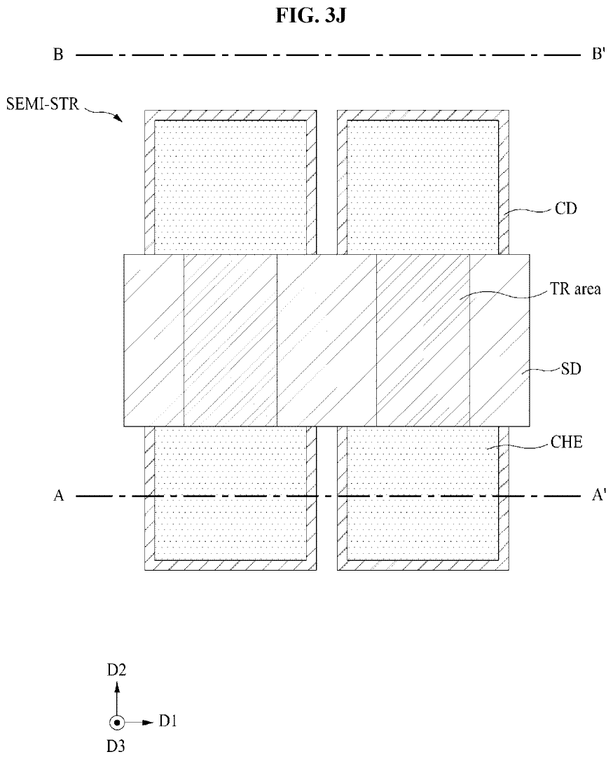

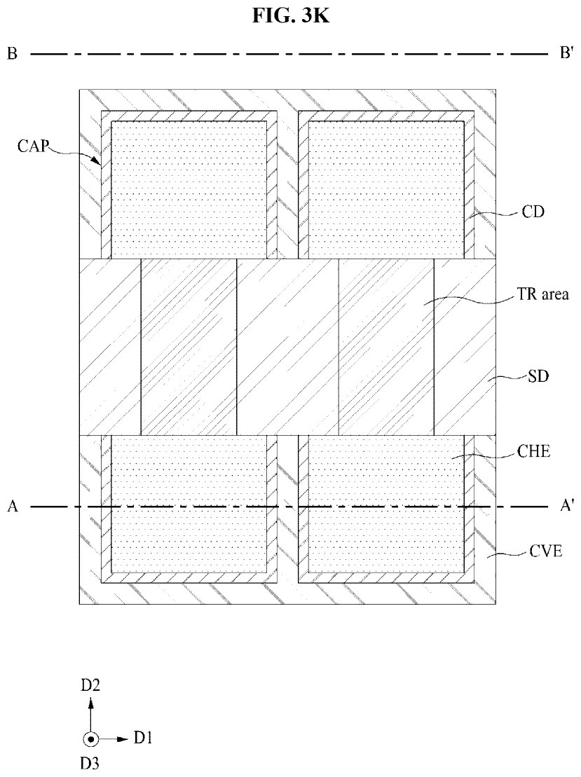

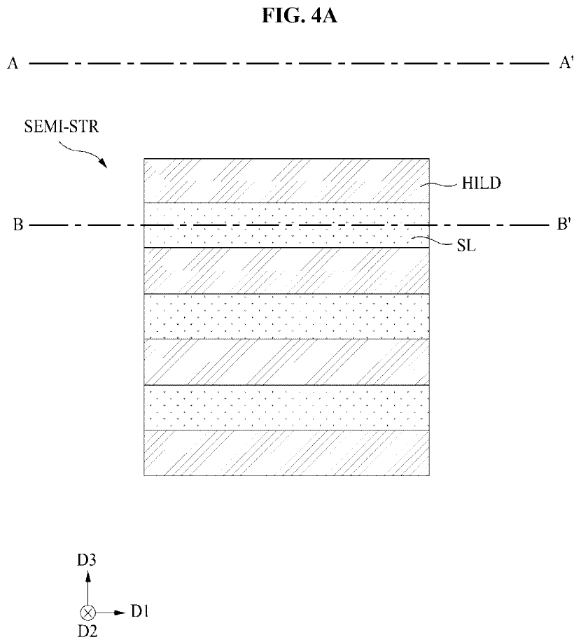

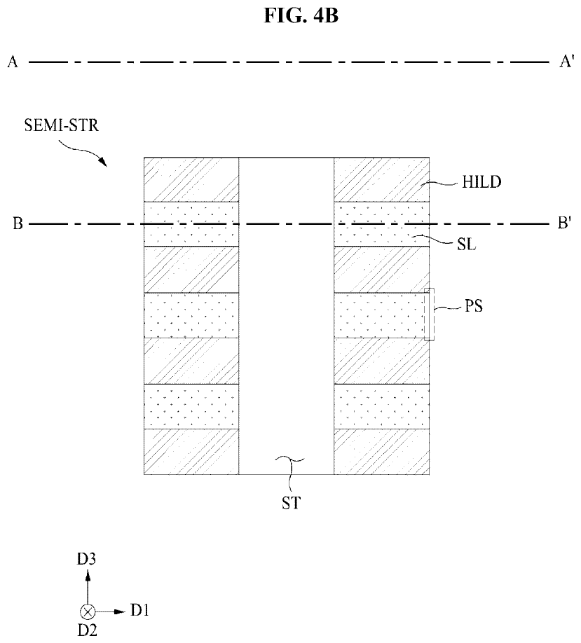

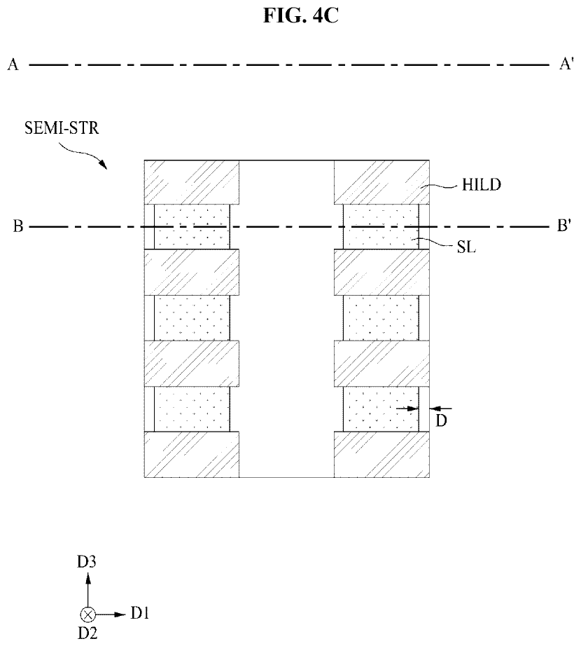

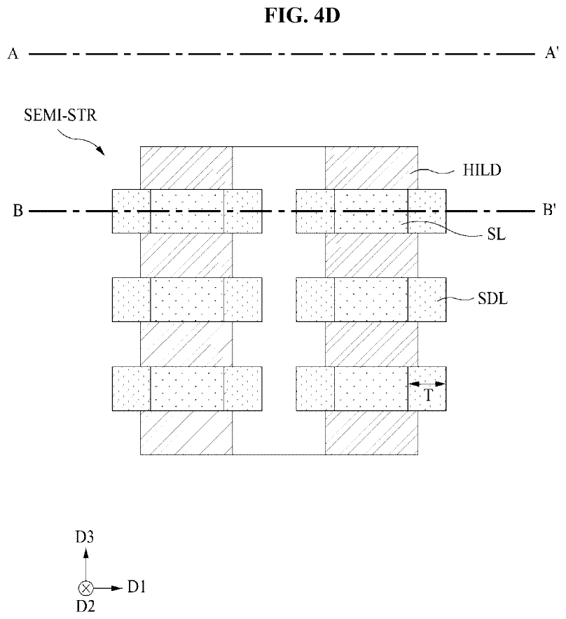

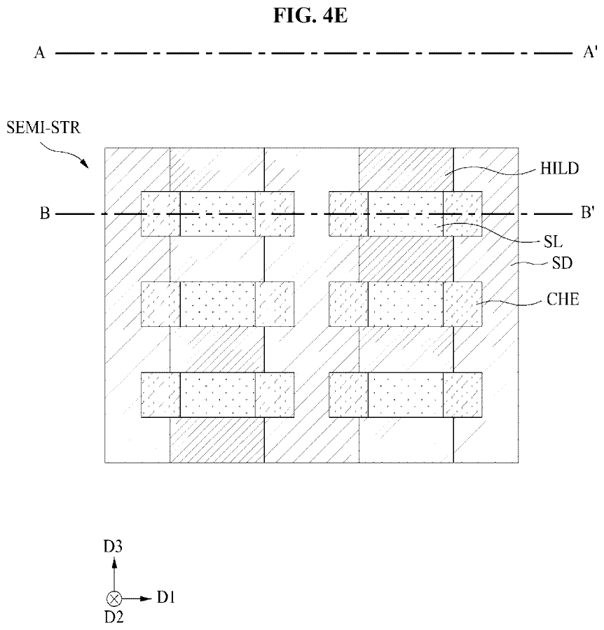

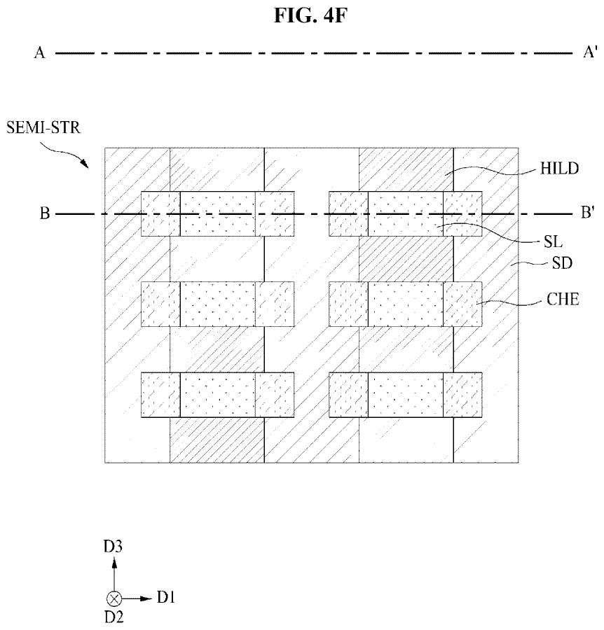

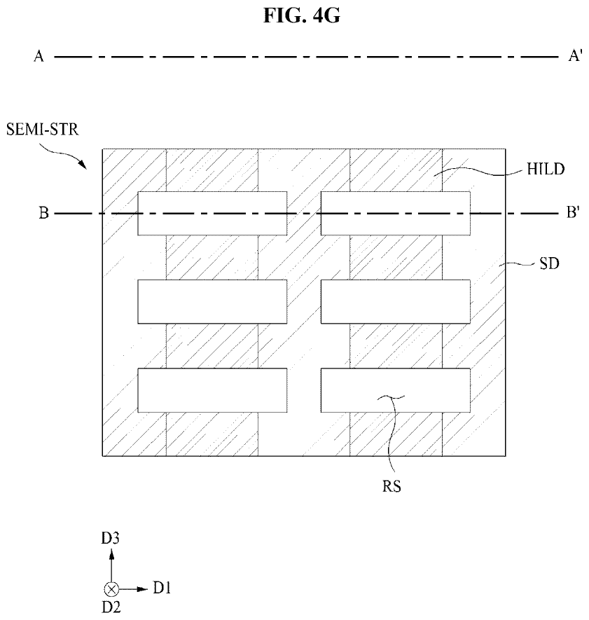

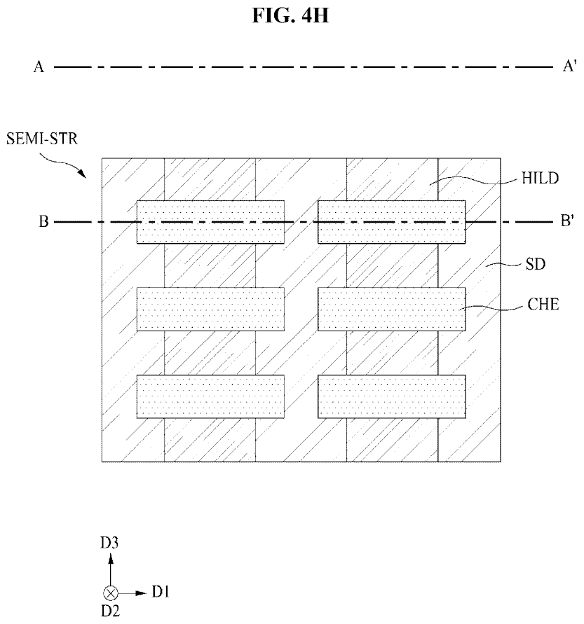

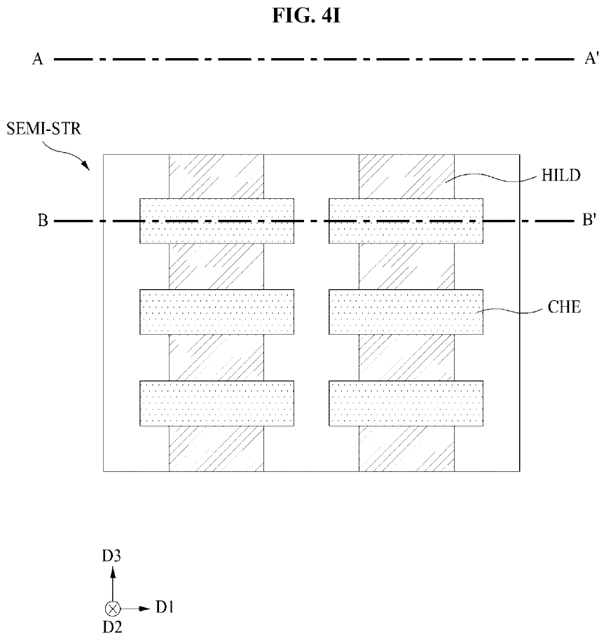

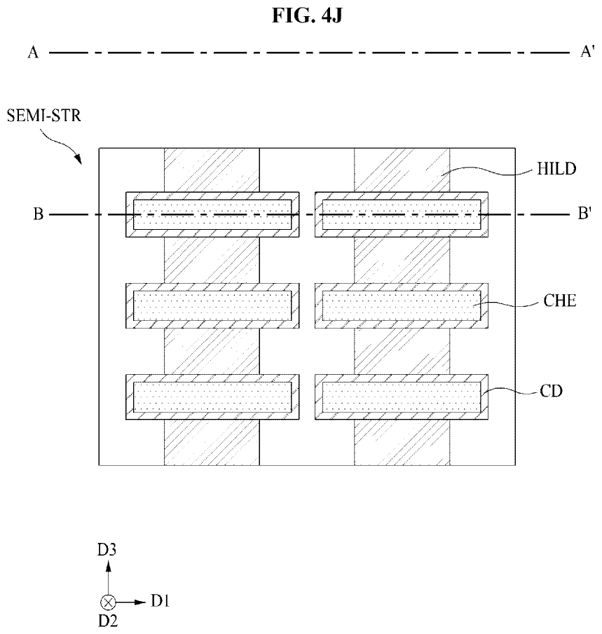

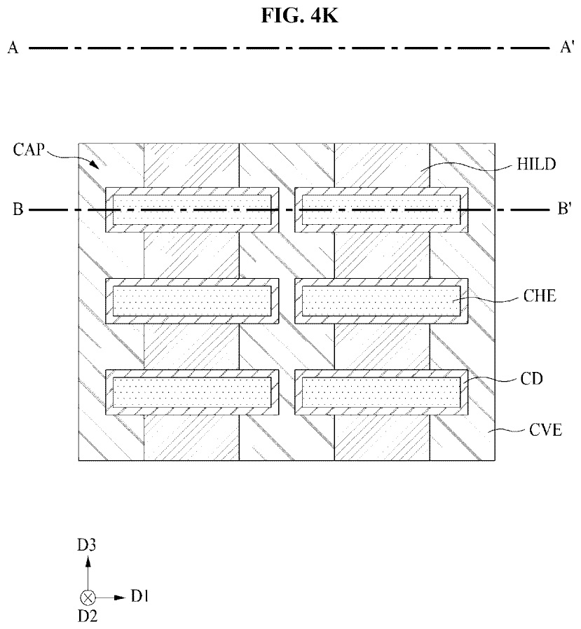

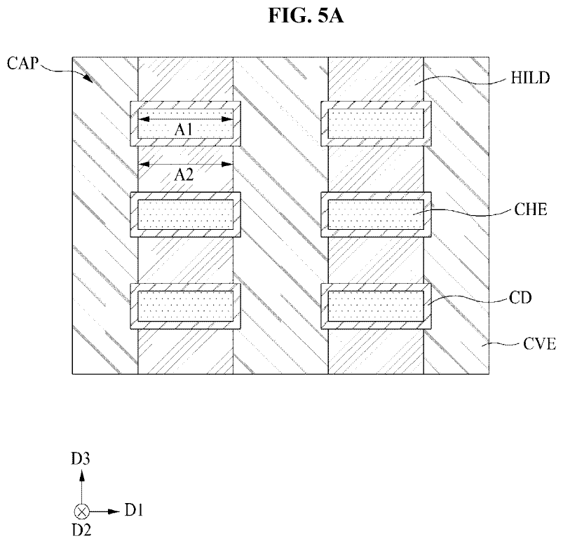

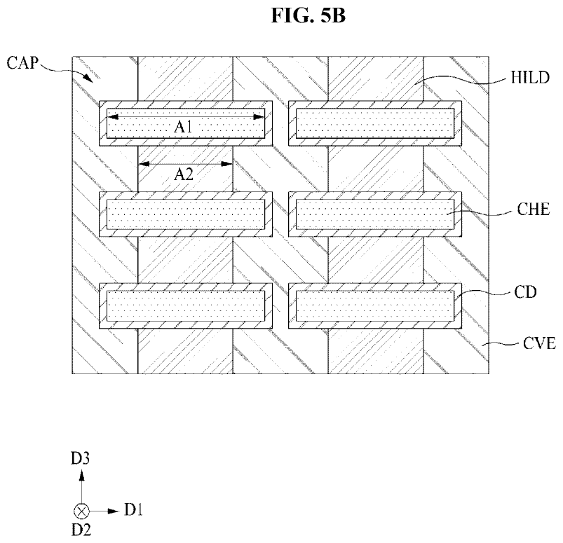

FIG. 2 is a flowchart illustrating a manufacturing method of a capacitor in a three-dimensional memory according to an example embodiment, FIGS. 3A to 3K are plan views illustrating the capacitor portion of the three-dimensional memory to explain the manufacturing method of the capacitor in the three-dimensional memory shown in FIG. 2, FIGS. 4A to 4K are side cross-sectional views illustrating the capacitor portion of the three-dimensional memory to explain the manufacturing method of the capacitor in the three-dimensional memory shown in FIG. 2, corresponding to cross-sections taken along line A-A′ of FIGS. 3A to 3J, and FIGS. 5A and 5B are side cross-sectional views illustrating a conventional three-dimensional DRAM and a three-dimensional memory according to an example embodiment to explain superiority of a capacitor structure of the three-dimensional memory according to an example embodiment.

Hereinafter, the described manufacturing method of a capacitor in a three-dimensional memory is for manufacturing the CAP included in the three-dimensional memory described with reference to FIGS. 1A and 1B, and is assumed to be performed by an automated and mechanized manufacturing system.

In Step S210, a manufacturing system may prepare a SEMI-STR (semiconductor structure) including HILDs and SLs alternately stacked in a vertical direction (e.g., the third direction D3) as illustrated in FIGS. 3A and 4A.

The HILDs may be formed of a dielectric material such as a low dielectric constant oxide film of SiO₂, Si₃N₄, SiON, and the like, and each of the SLs may be formed of a semiconductor material such as Si, SiGe or a material containing W or Mo.

At this time, the SEMI-STR may include a TR (transistor) previously formed in a TR area (transistor area), but is not limited thereto, and may be prepared such that the TR area, where the TR is to be formed, is defined in advance.

In Step S220, the manufacturing system may etch a ST (separate trench) in the SEMI-STR in a vertical direction (e.g., the third direction D3) as illustrated in FIGS. 3B and 4B.

The ST is a space for forming a SD (separate dielectric) for isolating the CAPs by device, and may be etched in the vertical direction at any positions of the SEMI-STR, considering locations where the CAPs will be formed by device. The etching depth may be such that the upper surface of the SUB is exposed. The etching method may use one of a dry etching method using a gas containing at least one of HCl and Cl2 and a wet etching method using a liquid containing at least one of KOH, TMAH, or ammonia water, but is not limited thereto.

In Step S230, the manufacturing system may remove one PS (portion of the side) of each of SLs through the ST as illustrated in FIGS. 3C and 4C.

Here, as a method for selectively etching the PS of each of SLs, one of a dry etching method using a gas containing at least one of HCl and Cl2 and a wet etching method using a liquid containing at least one of KOH, TMAH, or ammonia water may be used. In other words, in Step S230, the manufacturing system may selectively etch the PS of each of SLs by using any one of the dry etching method using a gas containing at least one of HCl and Cl2 and the wet etching method using a liquid containing at least one of KOH, TMAH, or ammonia water.

In Step S240, the manufacturing system may deposit each of SDLs (selective deposition layers) on the side surface of each of SLs from which the PS has been removed through the ST as illustrated in FIGS. 3D and 4D. As the deposition method, CVD or ALD may be used.

Particularly, in Step S240, the manufacturing system may determine a thickness T of each of the SDLs such that each of the SDLs deposited on the SLs protrudes in one direction of the horizontal direction (e.g., a first direction D1) beyond each of HILDs, and then deposit each of the SDLs according to the determined thickness T. For example, the thickness T of each of the SDLs may be determined to be greater than a depth D of the PS of each of SLs removed in Step S230. In a more specific example, if the depth D of the PS of each of SLs removed in Step S230 is 1 nm, the thickness T of each of the SDLs may be set to 3 nm.

As will be described later, since the SDLs must be removed together with the SLs in a single process, the SDLs may be formed of a material that can be collectively removed in a single process together with a material forming the SLs. That is, in Step S240, the manufacturing system may deposit each of the SDLs with the material that can be removed together with the material forming the SLs in a single process. For example, each of the SDLs may be formed of a semiconductor material such as Si or SiGe, or of a material containing W or Mo.

In Step S250, the manufacturing system may remove the SDLs and the SLs.

More specifically, as illustrated in FIGS. 3E and 4E, the manufacturing system may deposit the SD to surround the SEMI-STR, as illustrated in FIGS. 3F and 4F, may etch a CT (CHE trench) in the SD in a vertical direction (e.g., the third direction D3), and as illustrated in FIGS. 3G and 4G, may remove the SDLs and the SLs through the CT.

As described earlier, in Step S250, the manufacturing system may remove the SDLs and the SLs collectively in a single process. Accordingly, unlike in cases where the SDLs and the SLs are removed in separate processes, the removal process can be simplified.

In Step S260, as illustrated in FIGS. 3H and 4H, the manufacturing system may form each of CHEs (capacitor horizontal electrodes) in RSs (removed spaces) from which the SDLs and the SLs have been removed. The CHEs may be formed of a semiconductor material (e.g., polysilicon) or a conductive material (e.g., tungsten (W), copper (Cu), aluminum (Al), titanium (Ti), tantalum (Ta), molybdenum (Mo), ruthenium (Ru), gold (Au), platinum (Pt), iridium (Ir), titanium nitride (TiN), tantalum nitride (TaN), and the like).

As described above, because each of the SDLs deposited on the SLs protrudes in one direction of the horizontal direction (e.g., the first direction D1) beyond each of the HILDs, the RSs from which the SDLs and the SLs have been removed also protrude in one direction of the horizontal direction (e.g., the first direction D1) beyond each of the HILDs. Accordingly, in Step S260, the manufacturing system may form each of the CHEs in the RSs from which the SDLs and the SLs have been removed that protrude in one direction of the horizontal direction (e.g., the first direction D1) beyond each of the HILDs.

As a result, each of the CHEs may have a shape protruding in one direction of the horizontal direction (e.g., the first direction D1) beyond each of the HILDs, as each of the CHEs is formed in the RSs from which the SDLs and the SLs have been removed, protruding in one direction of the horizontal direction (e.g., the first direction D1) beyond each of the HILDs.

In this manner, each of the CHEs may be formed in a shape protruding in one direction of the horizontal direction (e.g., the first direction D1) beyond each of the HILDs, thereby having an increased horizontal area compared to each of the HILDs. Accordingly, Step S260 may be a step in which the CHEs are formed to have an increased horizontal area relative to the HILDs.

Although not illustrated as a separate step in FIG. 2, after Step S260, as shown in FIGS. 3I and 4I, the manufacturing system may etch at least a portion of the SEMI-STR to expose at least one surface of each of the CHEs, and then, as shown in FIGS. 3J and 4J, form at least one CD in contact with at least one surface of each of the CHEs.

As a material for forming at least one CD, an insulating material having insulating properties like a dielectric (e.g., silicon nitride film, aluminum oxide, hafnium oxide, zirconium oxide, titanium oxide, etc.) or a mixture thereof may be used.

Here, etching at least a portion of the SEMI-STR so that at least one surface of each of the CHEs is exposed may include etching a portion of the SD deposited to surround the SEMI-STR to expose at least one surface of each of the CHEs, or etching at least a portion of the SEMI-STR or the SD to separate each of the CHEs.

Although not illustrated as a separate step in FIG. 2, after at least one CD has been formed, the manufacturing system may form the CVEs so as to contact at least one surface of the at least one CD, as illustrated in FIGS. 3K and 4K. As materials for forming the CVEs, a semiconductor material (e.g., polysilicon) or a conductive material (e.g., tungsten (W), copper (Cu), aluminum (Al), titanium (Ti), tantalum (Ta), molybdenum (Mo), ruthenium (Ru), gold (Au), platinum (Pt), iridium (Ir), titanium nitride (TiN), tantalum nitride (TaN), and the like) may be used.

In contrast to a conventional three-dimensional DRAM in which a horizontal area A1 of the CHEs is restricted to be the same as a horizontal area A2 of the HILDs, as illustrated in FIG. 5A, the three-dimensional memory according to an embodiment may achieve the technical effect of increasing and enhancing capacitance values by proposing a structure in which the horizontal area A1 of the CHEs is larger than the horizontal area A2 of the CAP, as illustrated in FIG. 5B.

Although the example embodiments are described with reference to some specific example embodiments and accompanying drawings, it will be apparent to one of ordinary skill in the art that various alterations and modifications in form and details may be made in these example embodiments without departing from the spirit and scope of the claims and their equivalents. For example, suitable results may be achieved if the described techniques are performed in different order, and/or if components in a described system, architecture, device, or circuit are combined in a different manner, and/or replaced or supplemented by other components or their equivalents.

Therefore, other implementations, other example embodiments, and equivalents of the claims are to be construed as being included in the claims.

What is claimed is:

1. A manufacturing method of a capacitor in a three-dimensional memory, comprising:
preparing a semiconductor structure including horizontal inter layer dielectrics and sacrificial layers alternately stacked in a vertical direction;
etching a separate trench in the semiconductor structure in the vertical direction;
removing a portion of each side surface of the sacrificial layers through the separate trench;
depositing each of selective deposition layers on each side surface of the sacrificial layers, from which the portion has been removed, through the separate trench;
removing the selective deposition layers and the sacrificial layers; and
forming each of capacitor horizontal electrodes in spaces from which the selective deposition layers and the sacrificial layers have been removed,
wherein the depositing each of selective deposition layers is configured to deposit each of selective deposition layers such that each of the selective deposition layers deposited on the sacrificial layers protrudes in one direction of a horizontal direction beyond each of the horizontal inter layer dielectrics.

2. The manufacturing method of a capacitor in a three-dimensional memory of claim 1, wherein the forming each of capacitor horizontal electrodes is configured to form each of the capacitor horizontal electrodes in spaces from which the selective deposition layers and the sacrificial layers, protruding in one direction of the horizontal direction beyond each of the horizontal inter layer dielectrics, have been removed.

3. The manufacturing method of a capacitor in a three-dimensional memory of claim 2, wherein the capacitor horizontal electrodes are configured to have a shape protruding in one direction of the horizontal direction beyond each of the horizontal inter layer dielectrics, as the capacitor horizontal electrodes are formed in spaces from which the selective deposition layers and the sacrificial layers, protruding in one direction of the horizontal direction beyond each of the horizontal inter layer dielectrics, have been removed.

4. The manufacturing method of a capacitor in a three-dimensional memory of claim 3, wherein the forming each of the capacitor horizontal electrodes is configured to form each of the capacitor horizontal electrodes to have an increased horizontal area compared to each of the horizontal inter layer dielectrics.

5. The manufacturing method of a capacitor in a three-dimensional memory of claim 1, wherein the removing the selective deposition layers and the sacrificial layers is configured to collectively remove the sacrificial layers and the selective deposition layers through a single process.

6. The manufacturing method of a capacitor in a three-dimensional memory of claim 1, wherein the removing the selective deposition layers and the sacrificial layers comprises:
etching a capacitor horizontal electrode trench in the semiconductor structure in the vertical direction; and
removing the selective deposition layers and the sacrificial layers through the capacitor horizontal electrode trench.

7. The manufacturing method of a capacitor in a three-dimensional memory of claim 6, wherein the etching a capacitor horizontal electrode trench in the vertical direction further comprises:
depositing an insulating film to surround the semiconductor structure; and
etching the capacitor horizontal electrode trench in the vertical direction on the insulating film.

8. The manufacturing method of a capacitor in a three-dimensional memory of claim 1, further comprising forming at least one capacitor dielectric so as to be in contact with at least one surface of each of the capacitor horizontal electrodes.

9. The manufacturing method of a capacitor in a three-dimensional memory of claim 8, wherein the forming at least one capacitor dielectric further comprises etching at least a portion of the semiconductor structure so that at least one surface of each of the capacitor horizontal electrodes is exposed.

10. The manufacturing method of a capacitor in a three-dimensional memory of claim 8, further comprising forming a capacitor vertical electrode so as to be in contact with at least one surface of the at least one capacitor dielectric.

11. The manufacturing method of a capacitor in a three-dimensional memory of claim 1, wherein the removing a portion of each side surface of the sacrificial layers is configured to selectively etch a portion of each side surface of the sacrificial layers using one of a dry etching method using a gas containing at least one of HCl and Cl2 and a wet etching method using a liquid containing at least one of KOH, TMAH, or ammonia water.

12. A three-dimensional memory individually configuring a transistor and a capacitor, wherein the capacitor comprises:
horizontal inter layer dielectrics and capacitor horizontal electrodes alternately stacked in a vertical direction; and
at least one capacitor dielectric formed so as to be in contact with at least one surface of each of the capacitor horizontal electrodes,
wherein each of the capacitor horizontal electrodes has a shape protruding in one direction of a horizontal direction beyond each of the horizontal inter layer dielectrics.

13. The three-dimensional memory of claim 12, wherein each of the capacitor horizontal electrodes is configured to have an increased horizontal area compared to each of the horizontal inter layer dielectrics.

14. The three-dimensional memory of claim 12, wherein the capacitor further comprises a capacitor vertical electrode formed so as to be in contact with at least one surface of the at least one capacitor dielectric.
